(19) United States
(12) Patent Application Publication
(10) Pub. No.: US 2012/0083060 A1
(43) Pub. Date: Apr. 5, 2012

(54) INTEGRATION OF CLUSTER MOCVD AND HVPE REACTORS WITH OTHER PROCESS CHAMBERS

(76) Inventors: Jie Cui, Albany, CA (US); David Bour, Cupertino, CA (US); Liang-Yuh Chen, Foster City, CA (US)

(21) Appl. No.: 13/246,679

(22) Filed: Sep. 27, 2011

Related U.S. Application Data
(60) Provisional application No. 61/388,553, filed on Sep. 30, 2010.

(51) Int. Cl. H01L 33/04; C23C 16/30; C30B 25/02; C23C 16/44

(52) U.S. Cl. 438/46; 118/719; 257/E33.008

(57) ABSTRACT

The integration of cluster metal-organic chemical vapor deposition (MOCVD) and hydride vapor phase epitaxy (HVPE) reactors with other process chambers is described. For example, a method of fabricating a light-emitting diode (LED) structure described herein includes forming, in a first chamber of a cluster tool, a P-type group III-V material layer above a substrate. Without removing the substrate from the cluster tool a metal contact layer is formed directly on the P-type group III-V material layer in a second chamber of the cluster tool.

### CROSS-REFERENCE TO RELATED APPLICATIONS

This application claims the benefit of U.S. Provisional Application No. 61/388,553, filed Sep. 30, 2010, the entire contents of which are hereby incorporated by reference herein.

### BACKGROUND

1) Field

Embodiments of the present invention pertain to the field of light-emitting diode fabrication and, in particular, to the integration of cluster metal-organic chemical vapor deposition (MOCVD) and hydride vapor phase epitaxy (HVPE) reactors with other process chambers.

2) Description of Related Art

Group III-V materials are playing an ever increasing role in the semiconductor and related, e.g. light-emitting diode (LED), industries. Often, group III-V materials are difficult to grow or deposit without the formation of defects or cracks. For example, high quality surface preservation of select films, e.g. a gallium nitride film, is not straightforward in many applications using stacks of material layers fabricated sequentially.

### SUMMARY

Embodiments of the present invention pertain to the integration of cluster metal-organic chemical vapor deposition (MOCVD) and hydride vapor phase epitaxy (HVPE) reactors with other process chambers.

In an embodiment, a method of fabricating a light-emitting diode (LED) structure includes forming, in a first chamber of a cluster tool, a P-type group III-V material layer above a substrate. Without removing the substrate from the cluster tool a metal contact layer is formed directly on the P-type group III-V material layer in a second chamber of the cluster tool.

In an embodiment, a cluster tool for fabricating a light-emitting diode (LED) structure includes a first chamber for forming a P-type group III-V material layer above a substrate. The cluster tool also includes a second chamber for forming a metal contact layer directly on the P-type group III-V material layer. The cluster tool also includes a vacuum transfer chamber coupled to the first and second chambers for transferring the substrate between the first and second chambers.

### BRIEF DESCRIPTION OF THE DRAWINGS

FIG. 1 illustrates a cross-sectional view of a GaN-based light-emitting diode (LED), in accordance with an embodiment of the present invention.

FIG. 2 is a schematic plan view of a multi-chambered cluster tool for fabricating a light-emitting diode (LED) structure, in accordance with an embodiment of the present invention.

FIG. 3 is a Flowchart representing operations in a method of fabricating a light-emitting diode (LED) structure, in accordance with an embodiment of the present invention.

FIG. 4 is a schematic cross-sectional view of an MOCVD chamber, in accordance with an embodiment of the present invention.

FIG. 5 is a schematic view of an HVPE apparatus, in accordance with an embodiment of the present invention.

### DETAILED DESCRIPTION

The integration of cluster metal-organic chemical vapor deposition (MOCVD) and hydride vapor phase epitaxy (HVPE) reactors with other process chambers is described. In the following description, numerous specific details are set forth, such as cluster tool arrangements and material regimes, in order to provide a thorough understanding of embodiments of the present invention. It will be apparent to one skilled in the art that embodiments of the present invention may be practiced without these specific details. In other instances, well-known features, such as facility layouts or specific diode configurations, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

In light-emitting diode (LED) manufacturing, a metal contact or indium tin oxide (ITO) layer may be formed on a p-type gallium nitride (p-GaN) layer. The p-GaN layer may be the top layer of an aluminum indium gallium nitride (AlInGaN) based LED. However, the AlInGaN layer is typically the last later fabricated in, e.g., a metal organic chemical vapor deposition (MOCVD) chamber, prior to unloading a substrate supporting a partially fabricated LED structure from the confines of a processing tool. For example, following formation of an AlInGaN layer, the substrate is typically removed from a process tool housing an MOCVD chamber in which the AlInGaN layer is formed, and the substrate is then processed through the wet and/or dry cleaning processes in different process tools. The substrate is then typically loaded again into a deposition process chamber for ITO or metal deposition. The unload/load process described above thus includes an air break and surface clean process, either of which may undesirably provide interface contamination. Interface contamination in such fabricated stacks can result in higher forward voltages, yielding LEDs fabricated there from with a lower efficiency.

In accordance with an embodiment of the present invention, a metal contact or ITO deposition process chamber (e.g., an e-beam or PECVD process chamber) is integrated onto the same process tool platform with epitaxial chambers (e.g., HVPE or MOCVD, or both), so that substrates can be transferred from an epitaxial deposition chamber into a metal contact or ITO deposition chamber directly without air break. In one embodiment, there is no need to clean the substrate surface for ITO/metal deposition. In one embodiment, there is thus no pitting or oxidation impacting the critical layers of an LED device. In one embodiment, direct bonding between a layer formed in an epitaxial chamber and a layer formed in a metal contact or ITO deposition process chamber is more favorable than the situation where air breaks are used. In one embodiment, overall processing time is reduced. In an embodiment, one or more metal contact or ITO deposition process chambers is integrated with one or more HVPE or MOCVD chambers on a cluster tool with a common vacuum transfer chamber there between.

Described herein are cluster tools for fabricating light-emitting diode (LED) structures. In one embodiment, a cluster tool includes a first chamber for forming a P-type group III-V material layer above a substrate. The cluster tool also includes a second chamber for forming a metal contact layer directly on the P-type group III-V material layer. The cluster tool also includes a vacuum transfer chamber coupled to the first and second chambers for transferring the substrate between the first and second chambers.

Also disclosed herein are methods of fabricating light-emitting diode (LED) structures. In one embodiment, a method includes forming, in a first chamber of a cluster tool, a P-type group material layer above a substrate. The method also includes, without removing the substrate from the cluster tool, forming, in a second chamber of the cluster tool, a metal contact layer directly on the P-type group material layer.

Light-emitting diodes (LEDs) and related devices may be fabricated from layers of, e.g., group films. Some embodiments of the present invention relate to forming p-type gallium nitride (p-GaN) layers in a dedicated chamber of a cluster tool, such as in a dedicated metal-organic chemical vapor deposition (MOCVD) chamber or a dedicated hydride vapor phase epitaxy (HVPE) chamber of a cluster tool. A metal contact or ITO layer is then formed directly on the p-GaN layer in a different, dedicated, deposition process chamber of the same cluster tool. This arrangement reduces a potential for surface cross-contamination that would otherwise be observed between different processing tools. Key features of certain embodiments of the present invention include: (a) p-GaN material layer fabrication, (b) metal contact or ITO layer fabrication, or (c) LED fabrication. In some embodiments of the present invention, p-GaN is a p-type binary GaN film, but in other embodiments, p-GaN is a p-type ternary film (e.g., InGaN, AlGaN) or is a p-type quaternary film (e.g., InAlGaN).

In accordance with an embodiment of the present invention, fabrication of a GaN-based LED via epitaxy processing is performed in three major categories. The first category of processing includes fabrication of an n-type GaN template (e.g., n-type GaN, n-type InGaN, n-type AlGaN, n-type InAlGaN) on a substrate (e.g., planar sapphire substrate, patterned sapphire substrate (PSS), silicon substrate, silicon carbide substrate). The second category of processing includes fabrication of a multiple quantum well (MQW), or active region, structure or film stack on or above the n-type GaN template (e.g., an MQW composed of one or a plurality of field pairs of InGaN well/GaN barrier material layers) followed by fabrication of a p-type GaN (p-GaN) structure or film stack on or above the MQW. The p-GaN structure may be a single layer (such as, but not limited to, a single layer of p-type GaN, p-type InGaN, p-type AlGaN, or p-type InAlGaN), or may be a stack of multiple films. In a specific embodiment, the p-GaN structure is a film stack composed of p-type AlGaN and GaN layers. The third category of processing includes fabrication of a metal contact layer or an ITO layer on the p-GaN layer.

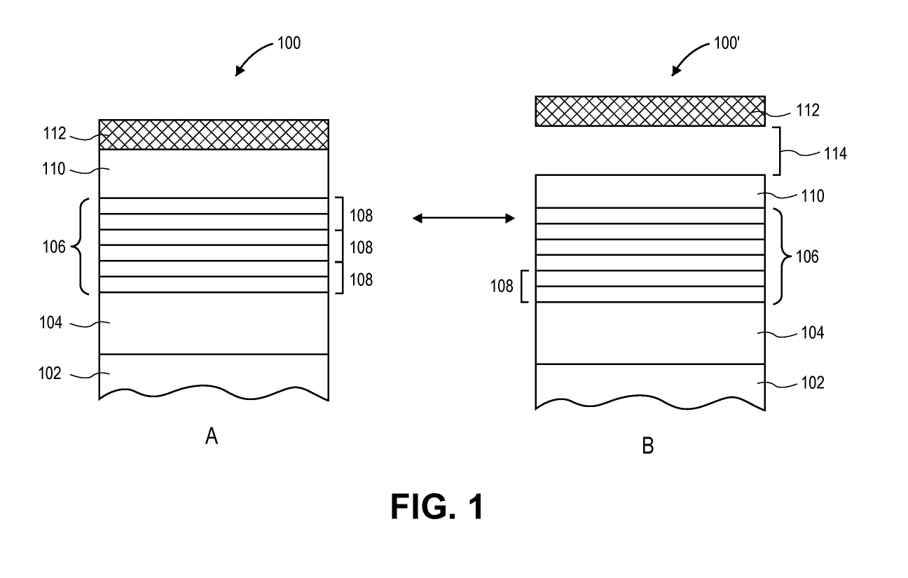

FIG. 1 illustrates a cross-sectional view of a GaN-based LED, in accordance with an embodiment of the present invention. Referring to the structure of part A of FIG. 1, a GaN-based LED 100 includes an n-type GaN template 104 (e.g., n-type GaN, n-type InGaN, n-type AlGaN, n-type InAlGaN) on a substrate 102 (e.g., planar sapphire substrate, patterned sapphire substrate (PSS), silicon substrate, silicon carbide substrate). The GaN-based LED 100 also includes a multiple quantum well (MQW), or active region, structure or film stack 106 on or above the n-type GaN template 104 (e.g., an MQW composed of one or a plurality of field pairs of InGaN well/GaN barrier material layers 108, as depicted in FIG. 1). The GaN-based LED 100 also includes a p-type GaN (p-GaN) layer or film stack 110 on or above the MQW 106, and a metal contact or ITO layer 112 on the p-GaN layer.

Referring to the structure of part B of FIG. 1, a GaN-based LED 100′ includes all of the features 102, 104, 106, 108, 110 and 112 of structure 100, but is shown to reveal an interface 114 between p-GaN feature 110 and metal contact or ITO layer 112 which conceptually exists during the time between the fabrication processes used to form metal contact or ITO layer 112 and p-GaN feature 110. In conventional fabrication approaches, interface 114 would be exposed to damaging conditions as the LED stack is fabricated in different process tools. The damaging conditions may cause interface 114 to become chemically contaminated during the transfer. In accordance with an embodiment, as described below, interface 114 is maintained in the same cluster tool and is not exposed to conditions outside of the cluster tool.

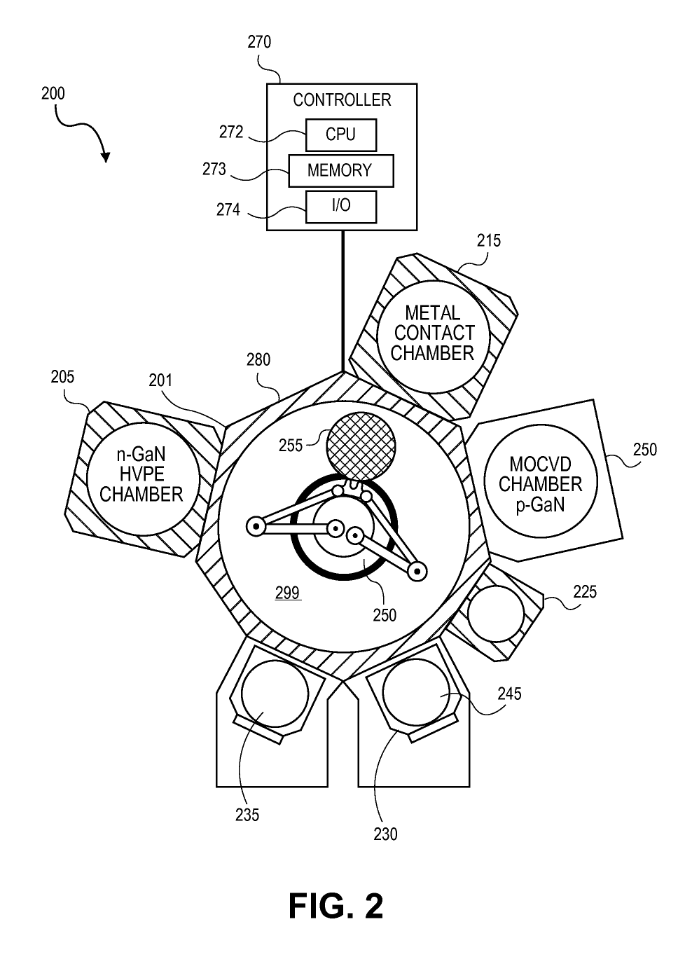

FIG. 2 is a schematic plan view of a multi-chambered cluster tool for fabricating a light-emitting diode (LED) structure, in accordance with an embodiment of the present invention.

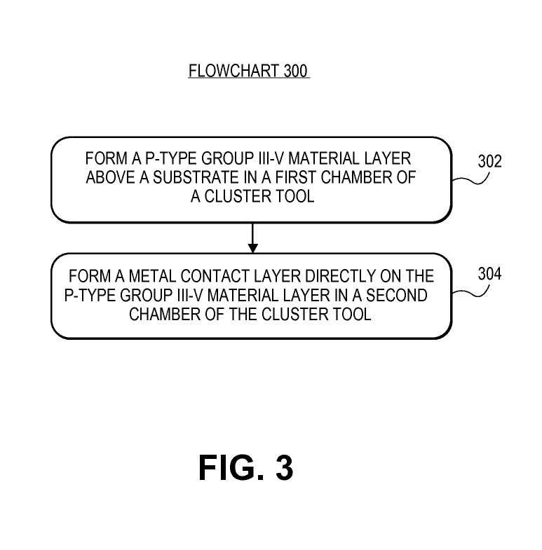

As shown in FIG. 2, a multi-chambered processing platform 200 may be a platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif. Embodiments of the present invention further include an integrated metrology (IM) chamber 225 as a component of the multi-chambered processing platform 200. The IM chamber 225 may provide control signals to allow adaptive control of integrated deposition process, such as the multiple segmented epitaxial growth described below in association with FIG. 3. Integrated metrology may be utilized as the substrate is transferred between epitaxy chambers and/or metal contact or ITO chambers. The IM chamber 225 may include a metrology apparatus suitable to measure various film properties, such as thickness, roughness, composition, and may further be capable of characterizing grating parameters such as critical dimensions (CD), sidewall angle (SWA), feature height (HT) under vacuum in an automated manner. Examples include, but are not limited to, optical techniques like reflectometry and scatterometry. In particularly advantageous embodiments, in-vacuo optical CD (OCD) techniques are employed where the attributes of a grating formed in a starting material are monitored as the epitaxial growth proceeds.

The epitaxy chambers 205 and 250 perform particular growth operations on a substrate, as described elsewhere herein. The deposition chamber 215 performs particular deposition operations on epitaxial layers, as is also described elsewhere herein. As further depicted in FIG. 2, the multi-chambered processing platform 200 further includes an optional substrate aligner chamber 255, as well as load lock chambers 230 holding cassettes 235 and 245, coupled to a transfer chamber 201 including a robotic handler 250. In one embodiment of the present invention, adaptive control of the multi-chambered processing platform 200 is provided by a controller 270. The controller 270 may be one of any form of general-purpose data processing system that can be used in an industrial setting for controlling the various subprocessors and subcontrollers. Generally, the controller 270 includes a central processing unit (CPU) 272 in communication with a memory 273 and an input/output (I/O) circuitry 274, among other common components. Software commands executed by the CPU 272, cause the multi-chambered processing platform 200 to, for example, load a substrate into the first hybrid epitaxy chamber 205, execute a first group III-nitride growth process. The substrate may then be further transferred to a second epitaxy chamber 250 and execute a further growth process (e.g., formation of active device layers of an LED stack).

In accordance with an embodiment of the present invention, referring to FIGS. 1 and 2, a cluster tool 200 for fabricating a light-emitting diode (LED) structure 100 is provided. The cluster tool 200 includes a first chamber 250 for forming a P-type group III-V material layer 110 above a substrate 102. A second chamber 215 is for forming a metal contact layer 112 directly on the P-type group III-V material layer 110. A vacuum transfer chamber 299 is coupled to the first and second chambers, 215 and 250, for transferring the substrate 102 between the first and second chambers.

In an embodiment, the first chamber 250 is for forming a p-GaN layer 110. In one embodiment, the second chamber 215 is for forming an indium tin oxide (ITO) layer 112 on the p-GaN layer 110. In an embodiment, the first chamber 250 of the cluster tool 200 is a metal organic chemical vapor deposition (MOCVD) reaction chamber. In one embodiment, the second chamber 215 of the cluster tool 200 is a plasma-enhanced chemical vapor deposition (PECVD) chamber. In a specific embodiment, the second chamber 215 is a physical vapor deposition chamber such as, but not limited to, an e-beam deposition chamber or a sputter chamber.

In an embodiment, cluster tool 200 further includes a third chamber 205 for forming an N-type group III-V material layer 104 above the substrate 102 prior to forming the P-type group III-V material layer 110. The cluster tool 100 also includes a fourth chamber (e.g., a chamber not shown but would be located in position 280) for forming a III-V material multiple quantum well stack 106 on the N-type group III-V material layer 104. The vacuum transfer chamber 299 is also coupled to the third and fourth chambers, 205 and a chamber in position 280, and is for transferring the substrate 102 between the third and fourth chambers (205 and a chamber in position 280) and between the fourth and first chambers (a chamber in position 280 and first chamber 250). In one embodiment, the first chamber 250 of the cluster tool 200 is a metal organic chemical vapor deposition (MOCVD) reaction chamber, the second chamber 215 is a chamber such as, but not limited to, a plasma-enhanced chemical vapor deposition (PECVD) chamber, an e-beam deposition chamber, or a sputter deposition chamber, the third chamber 205 is a hydride vapor phase epitaxy (HVPE) reaction chamber, and the fourth chamber (in position 280 of the cluster tool 200) is a metal organic chemical vapor deposition (MOCVD) reaction chamber.

In another embodiment, cluster tool 200 further includes a third chamber 205 for forming an N-type group III-V material layer 104 above the substrate 102. The first chamber 250 is also for forming a III-V material multiple quantum well stack 106 on the N-type group III-V material layer 104 prior to forming the P-type group III-V material layer 110. The vacuum transfer chamber 299 is also coupled to the third chamber 205 and is for transferring the substrate 102 between the third and first chambers, 205 and 250, respectively. In one embodiment, the first chamber 250 of the cluster tool 200 is a metal organic chemical vapor deposition (MOCVD) reaction chamber, the second chamber 215 is a plasma-enhanced chemical vapor deposition (PECVD) chamber, an e-beam deposition chamber or a sputter deposition chamber, and the third chamber 205 is a hydride vapor phase epitaxy (HVPE) reaction chamber.

FIG. 3 is a Flowchart representing operations in a method of fabricating a light-emitting diode (LED) structure, in accordance with an embodiment of the present invention.

Referring to operation 302 of Flowchart 300, and to corresponding FIGS. 1 and 2, a method of fabricating a light-emitting diode (LED) structure 100 includes forming, in a first chamber 250 of a cluster tool 200, a P-type group III-V material layer 110 above a substrate 102.

In an embodiment, forming the P-type group III-V material layer 110 includes forming a p-GaN layer. In one embodiment, forming the metal contact layer 112 includes forming an indium tin oxide (ITO) layer. In an embodiment, the first chamber 250 of the cluster tool 200 is a metal organic chemical vapor deposition (MOCVD) reaction chamber. In one embodiment, the second chamber 215 of the cluster tool 200 is a plasma-enhanced chemical vapor deposition (PECVD) chamber. In another embodiment, the second chamber 215 of the cluster tool 200 is a physical vapor deposition chamber such as, but not limited to, an e-beam deposition chamber or a sputter chamber.

Referring to operation 304 of Flowchart 300, and to corresponding FIGS. 1 and 2, the method of fabricating the light-emitting diode (LED) structure 100 also includes forming, in a second chamber 215 of the cluster tool 200, a metal contact layer 112 directly on the P-type group III-V material layer 110, without having removed the substrate 102 from the cluster tool 200.

In an embodiment, the method further includes forming, in a third chamber 205 of the cluster tool 200, an N-type group III-V material layer 104 above the substrate 102 prior to forming the P-type group III-V material layer 110. Then, without removing the substrate 102 from the cluster tool 200, the method also includes forming, in a fourth chamber (not depicted, but would be located in position 280 of the cluster tool 200), a III-V material multiple quantum well stack 106 on the N-type group III-V material layer 104. In one embodiment, the first chamber 250 is a metal organic chemical vapor deposition (MOCVD) reaction chamber, the second chamber 215 is a plasma-enhanced chemical vapor deposition (PECVD) chamber, an e-beam deposition chamber, or a sputter deposition chamber, the third chamber 205 is a hydride vapor phase epitaxy (HVPE) reaction chamber, and the fourth chamber is a metal organic chemical vapor deposition (MOCVD) reaction chamber.

In another embodiment, the method further includes forming, in a third chamber 205 of the cluster tool 200, an N-type group III-V material layer 104 above the substrate 102 prior to forming the P-type group III-V material layer 110. Then, without removing the substrate 102 from the cluster tool 200, the method also includes forming, in the first chamber 250 of the cluster tool 200, a III-V material multiple quantum well stack 106 on the N-type group III-V material layer 104. In one embodiment, the first chamber 250 is a metal organic chemical vapor deposition (MOCVD) reaction chamber, the second chamber 215 is a plasma-enhanced chemical vapor deposition (PECVD) chamber, an e-beam deposition chamber, or a sputter deposition chamber, and the third chamber 205 is a hydride vapor phase epitaxy (HVPE) chamber.

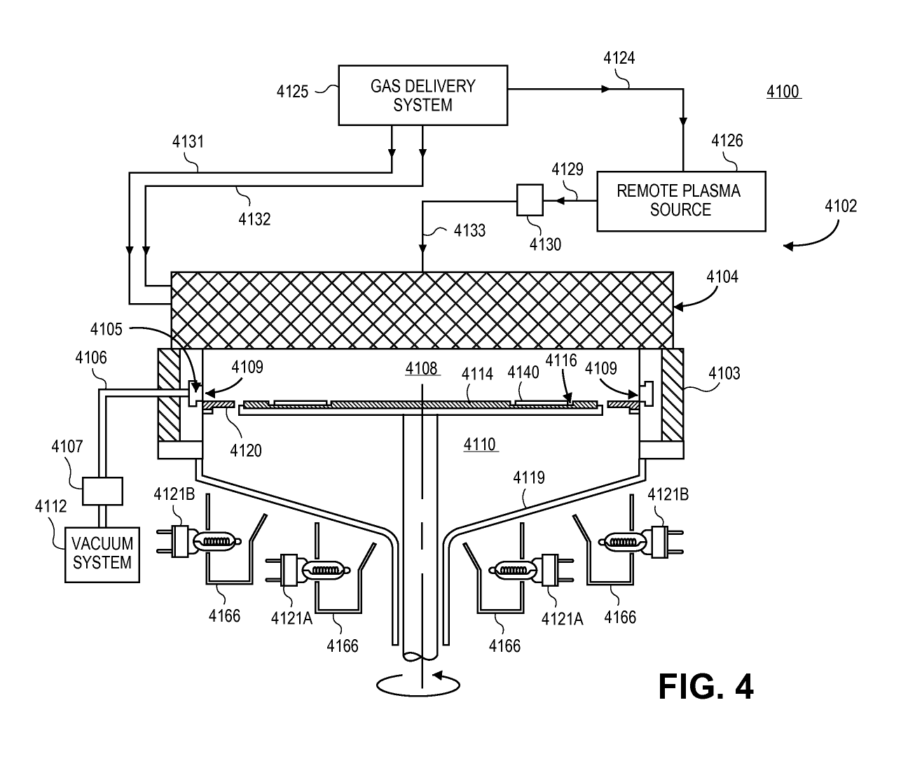

An example of an MOCVD deposition chamber which may be utilized for dedicated growth of p-GaN layer or a multiple quantum well stack, in accordance with embodiments of the present invention, is illustrated and described with respect to FIG. 4.

FIG. 4 is a schematic cross-sectional view of an MOCVD chamber according to an embodiment of the invention. Exemplary systems and chambers that may be adapted to practice the present invention are described in U.S. patent application Ser. No. 11/404,516, filed on Apr. 14, 2006, and Ser. No. 11/429,022, filed on May 5, 2006, both of which are incorporated by reference in their entireties.

The apparatus 4100 shown in FIG. 4 comprises a chamber 4102, a gas delivery system 4125, a remote plasma source 4126, and a vacuum system 4112. The chamber 4102 includes a chamber body 4103 that encloses a processing volume 4108. A showerhead assembly 4104 is disposed at one end of the processing volume 4108, and a substrate carrier 4114 is disposed at the other end of the processing volume 4108. A lower dome 4119 is disposed at one end of a lower volume 4110, and the substrate carrier 4114 is disposed at the other end of the lower volume 4110. The substrate carrier 4114 is shown in process position, but may be moved to a lower position where, for example, the substrates 4140 may be loaded or unloaded. An exhaust ring 4120 may be disposed around the periphery of the substrate carrier 4114 to help prevent deposition from occurring in the lower volume 4110 and also help direct exhaust gases from the chamber 4102 to exhaust ports 4109. The lower dome 4119 may be made of transparent material, such as high-purity quartz, to allow light to pass through for radiant heating of the substrates 4140. The radiant heating may be provided by a plurality of inner lamps 4121A and outer lamps 4121B disposed below the lower dome 4119, and reflectors 4166 may be used to help control chamber 4102 exposure to the radiant energy provided by inner and outer lamps 4121A, 4121B. Additional rings of lamps may also be used for finer temperature control of the substrate 4140.

The substrate carrier 4114 may include one or more recesses 4116 within which one or more substrates 4140 may be disposed during processing. The substrate carrier 4114 may carry six or more substrates 4140. In one embodiment, the substrate carrier 4114 carries eight substrates 4140. It is to be understood that more or less substrates 4140 may be carried on the substrate carrier 4114. Typical substrates 4140 may include sapphire, silicon carbide (SiC), silicon, or gallium nitride (GaN). It is to be understood that other types of substrates 4140, such as glass substrates 4140, may be processed. Substrate 4140 size may range from 50 mm-100 mm in diameter or larger. The substrate carrier 4114 size may range from 200 mm-750 mm. The substrate carrier 4114 may be formed from a variety of materials, including SiC or SiC-coated graphite. It is to be understood that substrates 4140 of other sizes may be processed within the chamber 4102 and according to the processes described herein. The showerhead assembly 4104 may allow for more uniform deposition across a greater number of substrates 4140 and/or larger substrates 4140 than in traditional MOCVD chambers, thereby increasing throughput and reducing processing cost per substrate 4140.

The substrate carrier 4114 may rotate about an axis during processing. In one embodiment, the substrate carrier 4114 may be rotated at about 2 RPM to about 100 RPM. In another embodiment, the substrate carrier 4114 may be rotated at about 30 RPM. Rotating the substrate carrier 4114 aids in providing uniform heating of the substrates 4140 and uniform exposure of the processing gases to each substrate 4140.

The plurality of inner and outer lamps 4121A, 4121B may be arranged in concentric circles or zones (not shown), and each lamp zone may be separately powered.

In one embodiment, one or more temperature sensors, such as pyrometers (not shown), may be disposed within the showerhead assembly 4104 to measure substrate 4140 and substrate carrier 4114 temperatures, and the temperature data may be sent to a controller (not shown) which can adjust power to separate lamp zones to maintain a predetermined temperature profile across the substrate carrier 4114. In another embodiment, the power to separate lamp zones may be adjusted to compensate for precursor flow or precursor concentration non-uniformity. For example, if the precursor concentration is lower in a substrate carrier 4114 region near an outer lamp zone, the power to the outer lamp zone may be adjusted to help compensate for the precursor depletion in this region.

The inner and outer lamps 4121A, 4121B may heat the substrates 4140 to a temperature of about 400 degrees Celsius to about 1200 degrees Celsius. It is to be understood that the invention is not restricted to the use of arrays of inner and outer lamps 4121A, 4121B. Any suitable heating source may be utilized to ensure that the proper temperature is adequately applied to the chamber 4102 and substrates 4140 therein. For example, in another embodiment, the heating source may comprise resistive heating elements (not shown) which are in thermal contact with the substrate carrier 4114.

A gas delivery system 4125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 4102. Different gases, such as precursor gases, carrier gases, purge gases, cleaning/etching gases or others may be supplied from the gas delivery system 4125 to separate supply lines 4131, 4132, and 4133 to the showerhead assembly 4104. The supply lines 4131, 4132, and 4133 may include shut-off valves and mass flow controllers or other types of controllers to monitor and regulate or shut off the flow of gas in each line.

A conduit 4129 may receive cleaning/etching gases from a remote plasma source 4126. The remote plasma source 4126 may receive gases from the gas delivery system 4125 via supply line 4124, and a valve 4130 may be disposed between the showerhead assembly 4104 and remote plasma source 4126. The valve 4130 may be opened to allow a cleaning and/or etching gas or plasma to flow into the showerhead assembly 4104 via supply line 4133 which may be adapted to function as a conduit for a plasma. In another embodiment, apparatus 4100 may not include remote plasma source 4126 and cleaning/etching gases may be delivered from gas delivery system 4125 for non-plasma cleaning and/or etching using alternate supply line configurations to shower head assembly 4104.

The remote plasma source 4126 may be a radio frequency or microwave plasma source adapted for chamber 4102 cleaning and/or substrate 4140 etching. Cleaning and/or etching gas may be supplied to the remote plasma source 4126 via supply line 4124 to produce plasma species which may be sent via conduit 4129 and supply line 4133 for dispersion through showerhead assembly 4104 into chamber 4102. Gases for a cleaning application may include fluorine, chlorine or other reactive elements.

In another embodiment, the gas delivery system 4125 and remote plasma source 4126 may be suitably adapted so that precursor gases may be supplied to the remote plasma source 4126 to produce plasma species which may be sent through showerhead assembly 4104 to deposit CVD layers, such as films, for example, on substrates 4140.

A purge gas (e.g., nitrogen) may be delivered into the chamber 4102 from the showerhead assembly 4104 and/or from inlet ports or tubes (not shown) disposed below the substrate carrier 4114 and near the bottom of the chamber body 4103. The purge gas enters the lower volume 4110 of the chamber 4102 and flows upwards past the substrate carrier 4114 and exhaust ring 4120 and into multiple exhaust ports 4109 which are disposed around an annular exhaust channel 4105. An exhaust conduit 4106 connects the annular exhaust channel 4105 to a vacuum system 4112 which includes a vacuum pump (not shown). The chamber 4102 pressure may be controlled using a valve system 4107 which controls the rate at which the exhaust gases are drawn from the annular exhaust channel 4105.

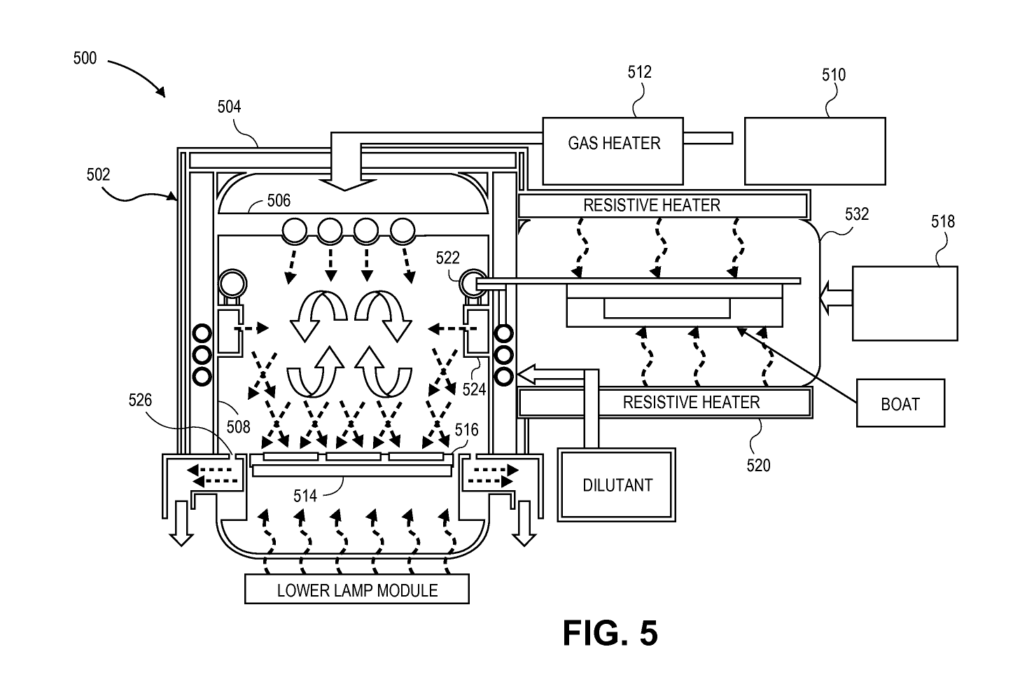

An example of a HVPE deposition chamber which may be utilized for dedicated growth of an n-GaN or a related film, in accordance with embodiments of the present invention, is illustrated and described with respect to FIG. 5.

FIG. 5 is a schematic view of an HVPE apparatus 500 according to one embodiment. The apparatus includes a chamber 502 enclosed by a lid 504. Processing gas from a first gas source 510 is delivered to the chamber 502 through a gas distribution showerhead 506. In one embodiment, the gas source 510 includes a nitrogen containing compound. In another embodiment, the gas source 510 includes ammonia. In one embodiment, an inert gas such as helium or diatomic nitrogen is introduced as well either through the gas distribution showerhead 506 or through the walls 508 of the chamber 502. An energy source 512 may be disposed between the gas source 510 and the gas distribution showerhead 506. In one embodiment, the energy source 512 includes a heater. The energy source 512 may break up the gas from the gas source 510, such as ammonia, so that the nitrogen from the nitrogen containing gas is more reactive.

To react with the gas from the first source 510, precursor material may be delivered from one or more second sources 518. The precursor may be delivered to the chamber 502 by flowing a reactive gas over and/or through the precursor in the precursor source 518. In one embodiment, the reactive gas includes a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the chamber 532 and be heated with the resistive heater 520. By increasing the residence time that the chlorine containing gas is snaked through the chamber 532, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactivity of the precursor, the precursor may be heated by a resistive heater 520 within the second chamber 532 in a boat. The chloride reaction product may then be delivered to the chamber 502. The reactive chloride product first enters a tube 522 where it evenly distributes within the tube 522. The tube 522 is connected to another tube 524. The chloride reaction product enters the second tube 524 after it has been evenly distributed within the first tube 522. The chloride reaction product then enters into the chamber 502 where it mixes with the nitrogen containing gas to form a nitride layer on a substrate 516 that is disposed on a susceptor 514. In one embodiment, the susceptor 514 includes silicon carbide. The nitride layer may comprise n-type gallium nitride for example. The other reaction products, such as nitrogen and chlorine, are exhausted through an exhaust 526.

It is to be understood that embodiments of the present invention are not limited to formation of layers on patterned sapphire substrates. Other embodiments may include the use of any suitable patterned single crystalline substrate upon which a Group III-Nitride epitaxial film may be formed. The patterned substrate may be formed from a substrate, such as but not limited to a sapphire (Al₂O₃) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate, and a lithium aluminum oxide (LiAlO₂) substrate. Any well know method, such as masking and etching may be utilized to form features, such as posts, from a planar substrate to create a patterned substrate. In a specific embodiment, however, the patterned substrate is a (0001) patterned sapphire substrate (PSS). Patterned sapphire substrates may be ideal for use in the manufacturing of LEDs because they increase the light extraction efficiency which is extremely useful in the fabrication of a new generation of solid state lighting devices. Other embodiments include the use of planar (non-patterned) substrates, such as a planar sapphire substrate.

In some embodiments, growth of a gallium nitride or related film on a substrate is performed along a (0001) Ga-polarity, N-polarity, or non-polar a-plane {112-0} or m-plane {101-0}, or semi-polar planes. In some embodiments, posts formed in a patterned growth substrate are round, triangular, hexagonal, rhombus shape, or other shapes effective for block-style growth. In an embodiment, the patterned substrate contains a plurality of features (e.g., posts) having a cone shape. In a particular embodiment, the feature has a conical portion and a base portion. In an embodiment of the present invention, the feature has a tip portion with a sharp point to prevent over growth. In an embodiment, the tip has an angle (Θ) of less than 145° and ideally less than 110°. Additionally, in an embodiment, the feature has a base portion which forms a substantially 90° angle with respect to the xy plane of the substrate. In an embodiment of the present invention, the feature has a height greater than one micron and ideally greater than 1.5 microns. In an embodiment, the feature has a diameter of approximately 3.0 microns. In an embodiment, the feature has a diameter height ratio of approximately less than 3 and ideally less than 2. In an embodiment, the features (e.g., posts) within a discrete block of features (e.g., within a block of posts) are spaced apart by a spacing of less than 1 micron and typically between 0.7 to 0.8 microns.

It is also to be understood that embodiments of the present invention need not be limited to n-GaN as a group III-V layer formed on a patterned substrate. For example, other embodiments may include any Group III-Nitride epitaxial film that can be suitably deposited by hydride vapor phase epitaxy or MOCVD, or the like, deposition.

The Group III-Nitride film may be a binary, ternary, or quaternary compound semiconductor film formed from a group III element or elements selected from gallium, indium and aluminum and nitrogen. That is, the Group III-Nitride crystalline film can be any solid solution or alloy of one or more Group III element and nitrogen, such as but not limited to GaN, AlN, InN, AlGaN, InGaN, InAlN, and InGaAlN. However, in a specific embodiment, the Group III-Nitride film is an n-type gallium nitride (GaN) film. The Group III-Nitride film can have a thickness between 2-500 microns and is typically formed between 2-15 microns. Thicknesses greater than 500 microns are possible because of, e.g., the high growth rate of HYPE. In an embodiment of the present invention, the Group III-Nitride film has a thickness of at least 3.0 microns to sufficiently suppress threading dislocations. Additionally, as described above, the Group III-Nitride film can be doped. The Group III-Nitride film can be p-typed doped using any p-type dopant such as but not limited Mg, Be, Ca, Sr, or any Group I or Group II element have two valence electrons. The Group III-Nitride film can be p-type doped to a conductivity level of between 1×10¹⁶ to 1×10²⁰ atoms/cm³.

It is to be understood that although the above description is focused on dedicated chambers within a cluster tool, other tools with more than one chamber, e.g. an in-line tool, may also be arranged to have a dedicated chamber for fabricating layers of an LED. Also, the n-GaN, p-GaN, or ITO portions need not be the only portion with a dedicated chamber. For example, as described above, dedicated chambers may be contemplated for the MQW portion of an LED.

It is also to be understood that embodiments of the present invention need not be limited to the fabrication of LEDs. For example, in another embodiment, devices other than LED devices may be fabricated in cluster tool 200, such as but not limited to field-effect transistor (FET) devices. In such embodiments, there may not be a need for a p-type material on top of a structure of layers. Instead, an n-type or un-doped material may be used in place of the p-type layer. However, in some embodiments, a metal deposition is still performed on the last epitaxial layer in the stack. Accordingly, in an embodiment, a cluster tool has a first chamber for epitaxially forming a semiconductor layer and a second chamber for depositing a metal or ITO contact layer.

Thus, approaches for the integration of cluster metal-organic chemical vapor deposition (MOCVD) and hydride vapor phase epitaxy (HVPE) reactors with other process chambers have been disclosed. In accordance with an embodiment of the present invention, a method of fabricating a light-emitting diode (LED) structure includes forming, in a first chamber of a cluster tool, a P-type group III-V material layer above a substrate. Without removing the substrate from the cluster tool, a metal contact layer is formed directly on the P-type group III-V material layer in a second chamber of the cluster tool. In accordance with another embodiment of the present invention, a cluster tool for fabricating a light-emitting diode (LED) structure includes a first chamber for forming a P-type group III-V material layer above a substrate. A second chamber is included for forming a metal contact layer directly on the P-type group III-V material layer. A vacuum transfer chamber is coupled to the first and second chambers for transferring the substrate between the first and second chambers.

What is claimed is:

1. A method of fabricating a light-emitting diode (LED) structure, the method comprising:
forming, in a first chamber of a cluster tool, a P-type group III-V material layer above a substrate; and, without removing the substrate from the cluster tool,
forming, in a second chamber of the cluster tool, a metal contact layer directly on the P-type group material layer.

2. The method of claim 1, wherein forming the P-type group III-V material layer comprises forming a p-GaN layer.

3. The method of claim 2, wherein forming the metal contact layer comprises forming an indium tin oxide (ITO) layer.

4. The method of claim 1, wherein the first chamber of the cluster tool is a metal organic chemical vapor deposition (MOCVD) reaction chamber.

5. The method of claim 4, wherein the second chamber of the cluster tool is a plasma-enhanced chemical vapor deposition (PECVD) chamber.

6. The method of claim 4, wherein the second chamber of the cluster tool is a physical vapor deposition chamber selected from the group consisting of an e-beam deposition chamber and a sputter chamber.

7. The method of claim 1, further comprising:
prior to forming the P-type group III-V material layer, forming, in a third chamber of the cluster tool, an N-type group III-V material layer above the substrate; and, without removing the substrate from the cluster tool,
forming, in a fourth chamber of the cluster tool, a III-V material multiple quantum well stack on the N-type group III-V material layer.

8. The method of claim 7, wherein the first chamber of the cluster tool is a metal organic chemical vapor deposition (MOCVD) reaction chamber, the second chamber of the cluster tool is selected from the group consisting of a plasma-enhanced chemical vapor deposition (PECVD) chamber, an e-beam deposition chamber and a sputter deposition chamber, the third chamber of the cluster tool is a hydride vapor phase epitaxy (HVPE) reaction chamber, and the fourth chamber of the cluster tool is a metal organic chemical vapor deposition (MOCVD) reaction chamber.

9. The method of claim 1, further comprising:
prior to forming the P-type group III-V material layer, forming, in a third chamber of the cluster tool, an N-type group III-V material layer above the substrate; and, without removing the substrate from the cluster tool,
forming, in the first chamber of the cluster tool, a III-V material multiple quantum well stack on the N-type group III-V material layer.

10. The method of claim 9, wherein the first chamber of the cluster tool is a metal organic chemical vapor deposition (MOCVD) reaction chamber, the second chamber of the cluster tool is selected from the group consisting of a plasma-enhanced chemical vapor deposition (PECVD) chamber, an e-beam deposition chamber and a sputter deposition chamber, and the third chamber of the cluster tool is a hydride vapor phase epitaxy (HVPE) reaction chamber.

11. A cluster tool for fabricating a light-emitting diode (LED) structure, the cluster tool comprising:
a first chamber for forming a P-type group III-V material layer above a substrate;
a second chamber for forming a metal contact layer directly on the P-type group III-V material layer; and
a vacuum transfer chamber coupled to the first and second chambers for transferring the substrate between the first and second chambers.

12. The cluster tool of claim 11, wherein the first chamber is for forming a p-GaN layer.

13. The cluster tool of claim 12, wherein the second chamber is for forming an indium tin oxide (ITO) layer on the p-GaN layer.

14. The cluster tool of claim 11, wherein the first chamber of the cluster tool is a metal organic chemical vapor deposition (MOCVD) reaction chamber.

15. The cluster tool of claim 14, wherein the second chamber of the cluster tool is a plasma-enhanced chemical vapor deposition (PECVD) chamber.

16. The cluster tool of claim 14, wherein the second chamber of the cluster tool is a physical vapor deposition chamber selected from the group consisting of an e-beam deposition chamber and a sputter chamber.

17. The cluster tool of claim 11, further comprising:
a third chamber for forming an N-type group III-V material layer above the substrate prior to forming the P-type group III-V material layer; and
a fourth chamber for forming a III-V material multiple quantum well stack on the N-type group III-V material layer, wherein the vacuum transfer chamber is also coupled to the third and fourth chambers and is for transferring the substrate between the third and fourth chambers and between the fourth and first chambers.

18. The cluster tool of claim 17, wherein the first chamber of the cluster tool is a metal organic chemical vapor deposition (MOCVD) reaction chamber, the second chamber of the cluster tool is selected from the group consisting of a plasma-enhanced chemical vapor deposition (PECVD) chamber, an e-beam deposition chamber and a sputter deposition chamber, the third chamber of the cluster tool is a hydride vapor phase epitaxy (HVPE) reaction chamber, and the fourth chamber of the cluster tool is a metal organic chemical vapor deposition (MOCVD) reaction chamber.

19. The cluster tool of claim 11, further comprising:
a third chamber for forming an N-type group III-V material layer above the substrate, wherein the first reaction chamber is for forming a III-V material multiple quantum well stack on the N-type group III-V material layer prior to forming the P-type group III-V material layer, and wherein the vacuum transfer chamber is also coupled to the third chamber and is for transferring the substrate between the third and first chambers.

20. The cluster tool of claim 19, wherein the first chamber of the cluster tool is a metal organic chemical vapor deposition (MOCVD) reaction chamber, the second chamber of the cluster tool is selected from the group consisting of a plasma-enhanced chemical vapor deposition (PECVD) chamber, an e-beam deposition chamber and a sputter deposition chamber, and the third chamber of the cluster tool is a hydride vapor phase epitaxy (HVPE) reaction chamber.
